(19) United States
(12) Patent Application Publication
(10) Pub. No.: US 2008/0001183 A1
(43) Pub. Date: Jan. 3, 2008

(54) Silicon-on-insulator (SOI) junction field effect transistor and method of manufacture

(76) Inventor: Ashok Kumar Kapoor, Palo Alto, CA (US)

Correspondence Address: WALKER & SAKO, LLP, Suite 235, 300 South First Street, San Jose, CA, 95113, US

(21) Appl. No.: 11/507,793

(22) Filed: Aug. 22, 2006

Related U.S. Application Data
(63) Continuation-in-part of application No. 11/261,873, filed on Oct. 28, 2005.
Application No. 11/261,873 is a continuation-in-part of application No. 11/452,442, filed on Jun. 13, 2006.
(60) Provisional application No. 60/799,787, filed on May 11, 2006.

(51) Int. Cl. H01L 29/80; H01L 29/00; H01L 31/112

(52) U.S. Cl. 257/256; 257/499

(57) ABSTRACT

A semiconductor device including complementary junction field effect transistors (JFETS) manufactured on a silicon on insulator (SOI) wafer is disclosed. A p-type JFET includes a control gate formed from n-type polysilicon and an n-type JFET includes a control gate formed from p-type polysilicon. The complementary JFETs may include four terminal JFETs having a back gate formed below a channel region. The back gate may be electrically connected to a control gate formed above a channel region via a cut region in an isolation structure. Furthermore, the complementary JFETs may be formed on strained silicon formed on a silicon germanium (SiGe) or silicon germanium carbon (SiGeC) layer, or the like.

This application claims the benefit of U.S. Provisional Patent Application Ser. No. 60/799,787, filed May 11, 2006, U.S. patent application Ser. No. 11/261,873, filed Oct. 28, 2005, and U.S. patent application Ser. No. 11/452,442, filed Jun. 13, 2006, the contents all of which are incorporated by reference herein.

### TECHNICAL FIELD

The present invention relates generally to semiconductor devices, and more particularly to semiconductor devices including a silicon-on-insulator (SOI) junction field effect transistor (JFET).

### BACKGROUND OF THE INVENTION

Junction field effect transistors can have advantages over a metal-oxide-semiconductor field effect transistor (MOSFET) as device sizes decrease. One particular advantage includes the absence of a thin gate insulating layer as found in a typical. MOSFET. However, because JFET devices are not typically used in today's semiconductor devices, little research has been performed on JFET devices in the last several decades.

One type of MOSFET is the silicon-on-insulator (SOI) MOSFET. Various types of SOI MOSFETs are well known. An example of an SOI MOSFET can be seen in “Silicon on Insulator Technology: Materials to VLSI” by Jean-Pierre Colinge, published by Kluwer Academic Publishing April 2004.

SOI technology includes a buried insulating layer, typically SiO₂, on a silicon substrate. The buried insulating layer can be formed using various techniques. One method includes oxidizing the surface of a first silicon wafer to create an insulating layer, bonding the oxidized wafer to a second wafer, and then polishing the second wafer off at a predetermined thickness. Another method can form a buried insulating layer with an ion implantation step that implants oxygen at a predetermined depth into a silicon substrate. Subsequently, a high temperature anneal step can result in the implanted oxygen creating a silicon dioxide (SiO₂) layer buried in the substrate.

A conventional SOI MOSFET can include a lateral MOS device formed on the buried insulating layer. SOI technology can have various advantages over bulk MOSFET technology, including but not limited to, junction depth reduction, immunity to soft errors, and speed improvements due to decreased capacitance.

### BRIEF DESCRIPTION OF THE DRAWINGS

FIG. 1 is a cross sectional diagram of complementary silicon on insulator (SOI) junction field effect transistor (JFET) devices according to an embodiment.

FIG. 2A is a circuit schematic diagram of an n-type JFET. FIG. 2B is a circuit schematic diagram of a p-type JFET.

FIGS. 3A to 3I are a series of cross sectional diagrams showing formation steps of complementary SOI JFET devices according to an embodiment.

FIG. 4A is a top plan view of complementary SOI four terminal JFET devices according to an embodiment. FIG. 4B is a cross section diagram of complementary SOI four terminal JFET devices according to an embodiment. FIG. 4C is a cross section diagram of an n-type SOI four terminal JFET devices according to an embodiment.

FIG. 5A is a circuit schematic diagram of a four terminal n-type JFET. FIG. 5B is a circuit schematic diagram of a four terminal p-type JFET

FIGS. 6A to 6K are cross sectional diagrams showing formation steps of complementary SOI JFET devices according to another embodiment

FIG. 7A is cross-sectional diagram of a semiconductor device including complementary JFET devices formed with strained silicon on silicon containing layer on insulator or strained silicon-on-insulator (SSOI) according to an embodiment.

FIGS. 7B to 7E are cross sectional diagrams showing formation steps of complementary JFET devices with strained silicon on silicon containing layer on insulator or strained silicon-on-insulator (SSOI) according to an embodiment.

FIG. 8 is a cross sectional diagram of complementary silicon on insulator (SOI) junction field effect transistor (JFET) devices according to an embodiment.

FIGS. 9A to 9L are a series of cross sectional diagrams showing formation steps of complementary SOI JFET devices according to an embodiment.

FIG. 10A is a top plan view of complementary SOI four terminal JFET devices according to an embodiment. FIG. 10B is a cross section diagram of complementary SOI four terminal JFET devices of FIG. 10A along the 10B-10B line according to an embodiment. FIG. 10C is a cross section diagram of complementary SOI four terminal JFET devices of FIG. 10A along the 10C-10C line according to an embodiment.

### DETAILED DESCRIPTION OF THE EMBODIMENTS

Various embodiments of the present invention will now be described in detail with reference to a number of drawings. The embodiments show a silicon-on-insulator (SOI) junction field effect transistor (JFET) and more particularly, complementary SOI JFETs, such as an SOI p-type JFET and SOI n-type JFET. Steps for manufacturing such devices are also described.

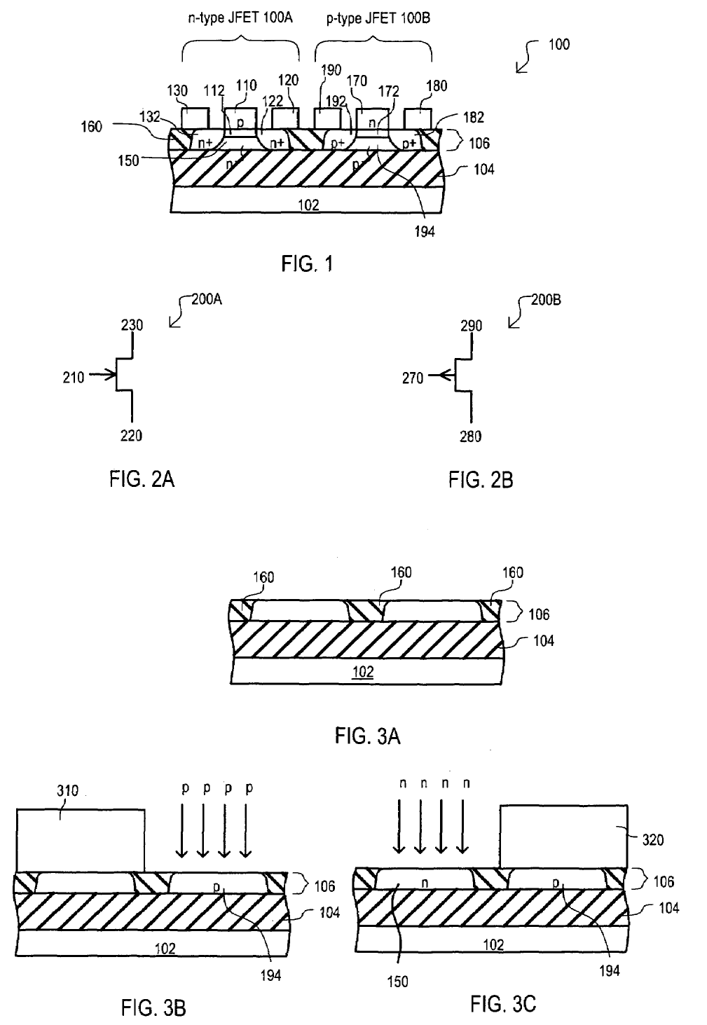

Referring now to FIG. 1, a cross-sectional diagram of a semiconductor device including complementary SOI JFET devices according to an embodiment is set forth and given the general reference character 100.

A semiconductor device 100 can include complementary JFETs (p-type and n-type) built on a SOI wafer. In the example shown, semiconductor device 200 includes a substrate 102, an insulating layer 104 and a device layer 106. Substrate 102 may be a silicon substrate, a quartz substrate, or other suitable material. Insulating layer 104 may be a silicon dioxide layer, or other suitable insulating layer. Device layer 106 can include silicon sections (e.g., islands or mesas) separated from one another by insulating areas. Device layer 106 may be less than 500 nm in thickness, preferably in the range of 50 nm to 200 nm in thickness.

In the example of FIG. 1, device layer 106 can include an n-type JFET 100A and a p-type JFET 100B formed therein. An n-type JFET 100A can include a gate formed from a p-doped polysilicon layer 110, a p-type diffusion layer 112, a first source/drain region formed from a n-type diffusion layer 122, a second source/drain region formed from a n-type diffusion layer 132, and a channel region 150. Channel region 150 may be n-type silicon. The n-type JFET 100A may further include a first source/drain contact 120 and a second source/drain contact 130. First and second source/drain contacts (120 and 130) may be n-doped polysilicon, as just one example.

A p-type JFET 100B may include a gate formed from an n-doped polysilicon layer 170, an n-type diffusion layer 172, a first source/drain region formed from a p-type diffusion layer 182, a second source/drain region formed from a p-type diffusion layer 192, and a channel region 194. Channel region 194 may be p-type silicon. A p-type JFET 100B may further include a first source/drain contact 180 and a second source drain contact 190. First and second source/drain contacts (180 and 190) may be p-doped polysilicon, as just one example.

An isolation structure, one of which is shown as 160, may electrically separate the n-type JFET 100A from the p-type JFET 100A. Isolation structure 160 may be silicon dioxide formed by a shallow trench isolation (STI) method, as but one example.

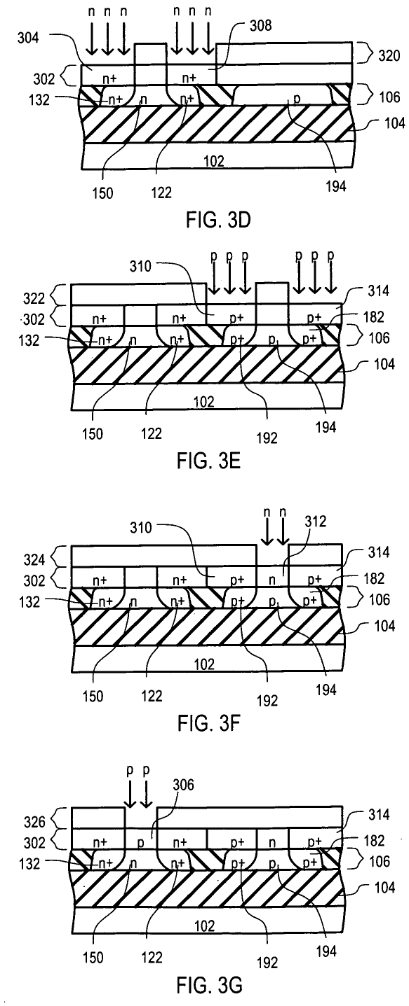

Referring to FIG. 2A, a circuit schematic diagram of the n-type JFET 100A of semiconductor device 100 is shown and given the general reference character 200A. N-type JFET 200A can include a gate terminal 210, a first source/drain terminal 220, and a second source/drain terminal 230. Gate terminal 210 can be used to control an impedance path between the first source/drain terminal 220 and the second source/drain terminal 230 by creating a depletion region within a channel region (e.g. 150 of FIG. 1).

In this way, complementary JFETs can be SOI structures.

Referring to FIG. 2B, a circuit schematic diagram of the p-type JFET 100B of semiconductor device 100 is shown and given the general reference character 200B. P-type JFET 200B includes a gate terminal 270, a first source/drain terminal 280, and a second source/drain terminal 290. Gate terminal 270 is used to control an impedance path between the first source/drain terminal 280 and the second source/drain terminal 290 by creating a depletion region within a channel region (e.g. 194 of FIG. 1).

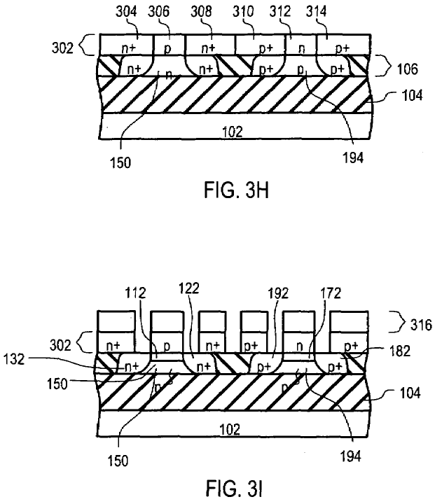

Having described the general structure of a semiconductor device that includes complementary SOI JFET, a method of manufacturing such a device will now be described with reference to FIGS. 3A to 3I. FIGS. 3A to 3I are side cross sectional views showing a semiconductor device after various manufacturing steps.

Referring now to FIG. 3A, a cross sectional diagram of a semiconductor device according to an embodiment after formation of isolation regions is set forth. Initially, a SOI wafer may include a substrate 102, an insulating layer 104, and a device layer 106. Device layer 106 can initially be a layer comprising silicon.

Trenches may be formed through device layer 106 to insulating layer 104 with an etching step. A thermal oxidation step may then be performed to round edges of such trenches. An insulating material may then be deposited over a resulting surface and within the trenches. Preferably such an insulating material can be a silicon oxide layer. A resulting structure can be planarized. For example, a chemical mechanical polishing (CMP) step can remove a deposited insulating material down to a device layer 106 resulting in isolation structures 160 that may separate active regions. Various passive or active devices can be formed in such active regions, including JFETs, such as a p-type JFET or n-type JFET as described above.

A semiconductor device following such steps is shown by FIG. 3A.

Referring now to FIG. 3B, formation of p-type regions are shown in a side cross sectional view. A method can thus include forming a mask layer 310 over regions not subject to a p-type implantation step. Exposed regions may then be subject to an ion implantation step with a p-type dopant such as boron, indium, or thallium to form a p-type region, which can be a channel region 194 of a p-type JFET. In one particular example, an implant dose can be in the range of about 2.0×10¹¹/cm² to 1.0×10¹⁴/cm². An implant energy can be in the range of about 1 to 100 KeV.

Subsequently, a mask layer 310 can be removed.

Referring now to FIG. 3C, formation of n-type regions are shown in a side cross sectional view. A method can thus include forming a mask layer 320 over regions not subject to an n-type implantation. Exposed regions may then be subject to an ion implantation step with an n-type dopant such as arsenic, phosphorous, or antimony may be performed to form an n-type region, which can be a channel region 150 of an n-type JFET. In one particular example, an implant dose can be in the range of about 2.0×10¹¹/cm² to 1.0×10¹⁴/cm². An implant energy can be in the range of about 1 to 100 KeV may be used.

An anneal step such as a rapid thermal anneal or a furnace anneal may then be performed.

Referring now to FIG. 3D, a cross sectional diagram of a semiconductor device following the formation of a polysilcon layer 302 over device layer 106. A mask layer 320 may be patterned and etched over the semiconductor device to expose only portions contacts (304 and 308) of polysilicon layer 302 which may later be used to provide source and drain contacts of an n-channel JFET. An implant step may then be performed of with n-type impurities such as phosphorous, arsenic, or antimony with a dose in the range of about 1.0×10¹³/cm² to 1.0×10¹⁶/cm². The implant energy may be sufficient to provide n-type impurities into source and drain (132 and 122).

Subsequently, mask layer 320 can be removed.

Referring now to FIG. 3E, a cross sectional diagram of a semiconductor device following the pattern and etch of a mask layer 322. Mask layer 322 may be patterned and etched over the semiconductor device to expose only portions (310 and 314) of polysilicon layer 302 which may later be used to provide source and drain contacts of a p-channel JFET. An implant step may then be performed of with a p-type impurity, such as boron, with a dose ranging between 1.0×10¹³/cm² to 1.0×10¹⁶/cm². The implant energy may be sufficient to provide n-type impurities into source and drain (182 and 192).

Subsequently, mask layer 322 can be removed.

Referring now to FIG. 3F, a cross sectional diagram of a semiconductor device following the pattern and etch of a mask layer 324. Mask layer 324 may be patterned and etched over the semiconductor device to expose only a portion 312 of polysilicon layer 302 which may later be used to provide a gate contact of a p-channel JFET. An implant step may then be performed of with with n-type impurities such as phosphorous, arsenic, or antimony with a dose in the range of about 1.0×10¹³/cm² to 1.0×10¹⁶/cm².

Subsequently, mask layer 324 can be removed.

Referring now to FIG. 3G, a cross sectional diagram of a semiconductor device following the pattern and etch of a mask layer 326. Mask layer 326 may be patterned and etched over the semiconductor device to expose only a portion 306 of polysilicon layer 302 which may later be used to provide a gate contact of a n-channel JFET. An implant step may then be performed of with with a p-type impurity, such as boron, with a dose ranging between 1.0×10¹³/cm² to 1.0×10¹⁶/cm².

Subsequently, mask layer 326 can be removed.

Referring now to FIG. 3H, a cross sectional diagram of a semiconductor device following the formation and selective doping of a polysilicon layer is shown in a cross sectional view. A method can include depositing a polysilicon layer 302 over a device layer 106. In one particular example, a polysilicon layer 302 can have a thickness in the range of about 100 and 10,000 angstroms. Multiple layers consisting of Si—Ge—C (silicon germanium carbon) alloys of varying composition may also be used for layer 302.

Referring still to FIG. 3H, a polysilicon layer 302 can be selectively doped to form differently doped regions. Such differently doped regions can form source, drain, and gate contacts of JFETs. Such differently doped regions can be formed with masking and ion implantation techniques as set forth in FIGS. 3D to 3G. If a polysilicon layer 302 is initially undoped, separate implant masks can be utilized for n-doped and p-doped regions. Highly doped n+ type poly regions for source/drain contacts for n-type JFETs may share an implant step with n-type poly regions for forming gate contacts for p-type JFETs, or may be separately doped. Similarly, highly doped p+ type poly regions for forming source/drain contacts for p-type JFETs may share an implant step with p-type poly regions for forming gate contacts for n-type JFETs, or may be separately doped. If a polysilicon layer 302 is doped in situ to a particular conductivity type, an implantation step can be omitted.

It is understood that regions 304 and 308 can have a different dopant concentration than region 312 and thus either can be subject to an additional implantation step. Regions 310 and 314 can have different dopant concentration than region 306 and thus either can be subject to an additional implantation step.

A protective layer (not shown) may be formed on polysicon layer 302 during such ion implantation steps.

Referring now to FIG. 3I, a cross sectional diagram of a semiconductor device following the outdiffusion of polysilicon dopants following an anneal step, such as a rapid thermal anneal, is shown in a cross sectional view. A method can include impurities implanted into polysilicon layer 302 out diffusing into various underlying regions of device layer 106, to form all or a portion of source/drains (122, 132, 182, and 192), and gates (112 and 172) in a device layer 106. A combination of outdiffusion and implant steps illustrated in FIGS. 3D to 3G may be used to form source/drains (122, 132, 182, and 192).

Referring still to FIG. 3I, a method can also include patterning a selectively doped polysilicon layer. An etch mask layer 316 can be formed over polysilicon layer 302, and an etching step can take place that forms source contacts, drain contacts, and gate contacts forth. Mask layer 316 can then be removed and a semiconductor device 100 having complementary SOI JFETs may be formed in accordance with FIG. 1.

Referring again to FIG. 3I, it is noted that in other embodiments, source/drain regions (122 and 132) for an n-type JFET exposed by an etch mask 316 may be further implanted with n-type impurities selectively (with a mask over p-type JFETs) to form a link region to provide a low resistance connection between the channel and the source/drain contacts (120 and 130) of n-type JFETs. In the same fashion, exposed source/drain regions (182 and 192) for p-type JFET may be further implanted with p-type impurities selectively to form a link region to provide a low resistance connection between the channel and the source/drain contacts (180 and 190).

Subsequently, mask layer 316 and other mask layers used to protect against link implants may be removed.

In yet further steps, a metal such as nickel, cobalt, titanium, platinum, palladium, or other refractory metal may be deposited on polysilicon layer 302 to form a silicide to reduce resistance of polysilicon layer 302 and/or provide a low impedance connection thereto.

In this way, a semiconductor device, such as semiconductor device 100 of FIG. 1, having complementary type SOI JFETs can be formed.

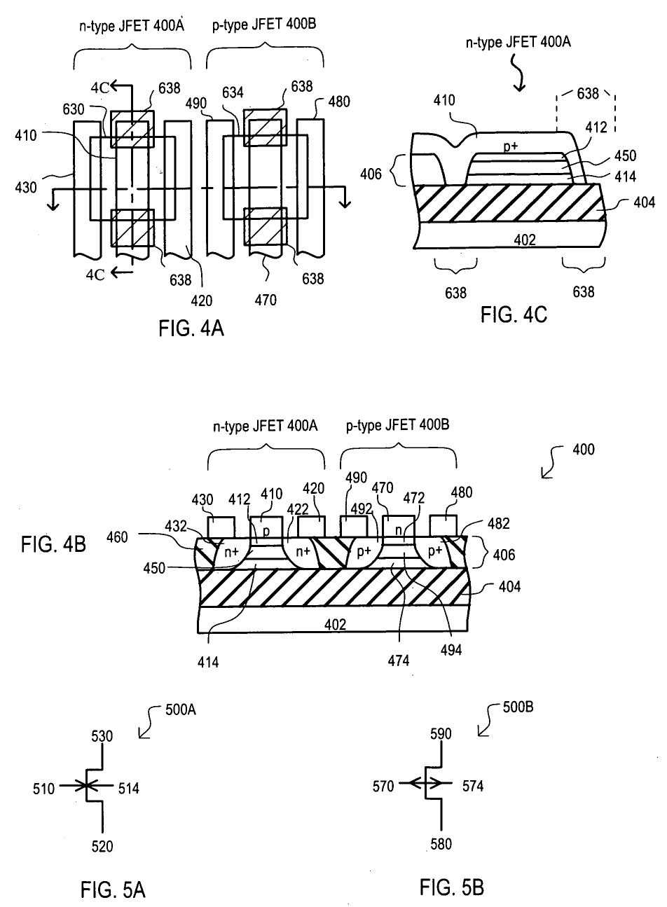

While embodiments of the invention can include SOI JFETs having single control gates, other embodiments can include a novel double gate, or “four terminal” SOI JFET device. Particular examples of such embodiments will now be described with reference to FIGS. 4A to 6K.

Referring now to FIG. 4A, a top plan view of portions of complementary four terminal SOI JFETs according to an embodiment is set forth. The floor plan of FIG. 4A includes an n-type four terminal SOI JFET 400A and a p-type four terminal SOI JFET 400B. N-type four terminal SOI JFET 400A includes polysilicon lines 420 and 430 that can be used to form the source and drain contacts and a polysilicon line 410 that can be used to form a front control gate of the n-type four terminal SOI JFET 400A. Also illustrated is an active area 630 which can be a semiconductor region surrounded by an isolation structure, such as a STI structure 460 like that shown in FIG. 4B. Active area 630 can be the portion of device layer 406 in which n-type four terminal SOI JFET 400A may be formed. P-type four terminal SOI JFET 400B includes polysilicon lines 480 and 400 that can be used to form the source and drain contacts and a polysilicon line 470 that can be used to form a front control gate of the p-type four terminal SOI JFET 400B. Also illustrated is an active area 634 which can be a semiconductor region surrounded by an isolation structure, such as a STI structure 460 like that shown in FIG. 4B. Active area 634 can be the portion of device layer 406 in which p-type four terminal SOI JFET 400B may be formed.

The top plan view of FIG. 4A also includes cut regions 638. Cut regions are regions in which the isolation structure can be etched away to expose the back gate 414 (in the case of a n-type JFET 400A) or back gate 474 (in the case of a p-type JFET 400B). Referring now to FIG. 4B, a cross section diagram of a semiconductor device having a complementary SOI four terminal JFET devices according to an embodiment is set forth and given the general reference character 400. FIG. 4B is a cross-section of FIG. 4A along the 4B-4B line. Semiconductor device 400 may include similar constituents as semiconductor device 100 and such constituents may have the same general reference character except the first digit can be a “4” instead of a “1” and a description thereof may be omitted.

Semiconductor device 400 may differ from semiconductor device 100 in that an n-type JFET 400A and p-type JFET 400B include a substrate area (414 and 474) of the same conductivity type as a control gate, but on the opposite side of the channel from the control gate. Such substrate areas will be referred to as “wells38 , but are not meant to imply any particular formation steps.

In more detail, n-type JFET 400A may include a well 414 that is p-type and p-type JFET 400B may include a well 474 that is n-type. Well 414 may operate as a “back” control gate to the n-type JFET and well 474 may operate as a ♭back” gate to the p-type JFET. By providing a contact to each well (414 and 474), such back gates may operate independently of “front” gates (i.e., 410 and 470), thus allowing complementary SOI four JFETs to be four terminal devices, each having a first source/drain, second source/drain, front gate, and back gate.

In this way, embodiments can include a semiconductor device with four terminal complementary SOI JFET devices.

Referring now to FIG. 4C, a cross sectional diagram of the semiconductor device along the line 4C-4C of FIG. 4A according to an embodiment is set forth. The cross-section of FIG. 4C illustrates one method of forming contact to the back gate 414 or 474 for a p-type four terminal SOI JFET. In particular, cut regions 638 may be regions in which a trench isolation has been etched away. In this way, when a gate terminal 410 (or gate terminal 470 in the case of the p-type four terminal SOI JFET) can provide contact to both the front control gate 412 and back control gate 414 (or front control gate 472 and back control gate 474 in the case of the p-type four terminal SOI JFET) A cross sectional diagram of a four terminal p-type JFET can look essentially the same as illustrated in FIG. 4C, except conductivity types are reversed.

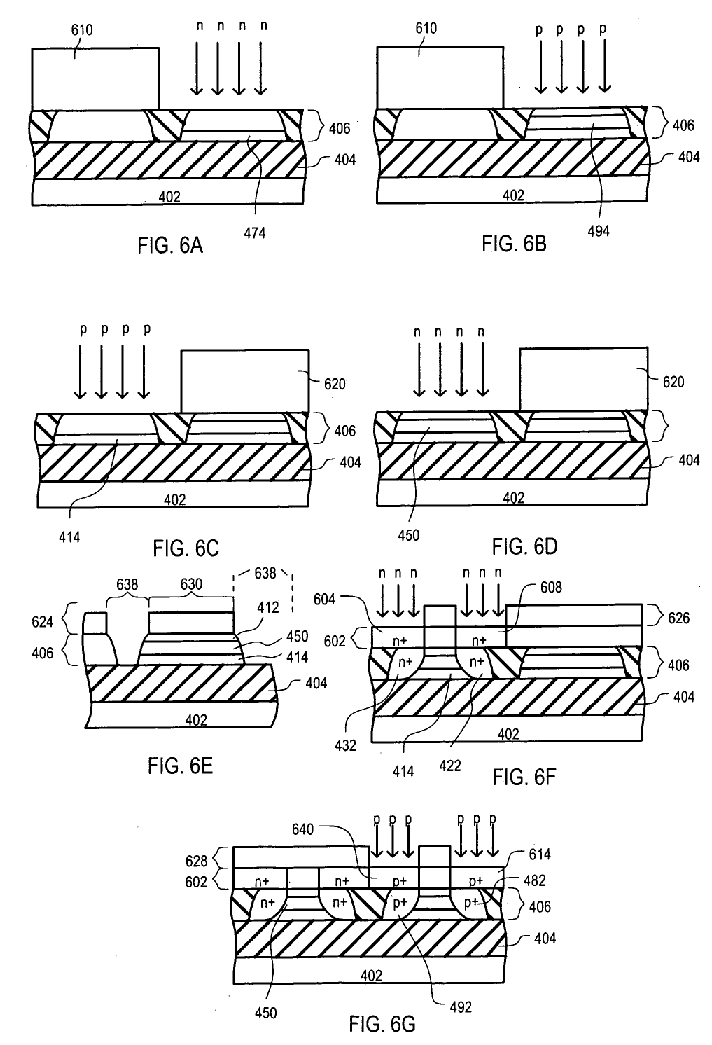

FIG. 5A is a schematic diagram of a four terminal n-type JFET 500A including a back gate terminal 514 that can be formed with a p-well. In more detail, four terminal n-type JFET 500A may include a front gate terminal 510, a back gate terminal 514 (formed from p-well 414 of FIG. 4), a first source/drain terminal 520, and a second source/drain terminal 530.

FIG. 5B is a schematic diagram of a four terminal p-type JFET 500B including a back gate terminal 574 formed with a n-well. Four terminal n-type JFET 500B may include a front gate terminal 570, a back gate terminal 574 (formed from n-well 474 of FIG. 4), a first source/drain terminal 580, and a second source/drain terminal 590.

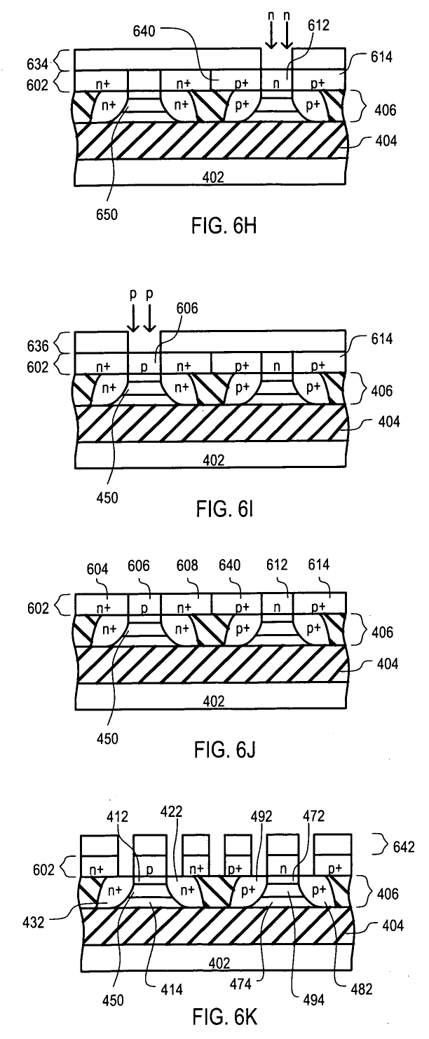

Having described the general structure of a semiconductor device that includes complementary four terminal SOI JFETs, a method of manufacturing such a device will now be described with reference to FIGS. 6A to 6K. FIGS. 6A to 6K are side cross sectional views showing a semiconductor device after various manufacturing steps.

A method of manufacturing semiconductor device 400 having complementary four terminal SOI JFETs may differ from that of FIGS. 3A to 3I in that a step for forming p-well 414 and n-well 474 (utilized as back gates) as well as contacts to each respective well (414 and 474) may be included. For example, p-well 414 and n-well 474 may be formed through appropriate ion implantation steps before the formation of channel regions (450 and 492). In addition, well contacts may be formed by depositing a polysilicon layer after forming isolation trenches, but before filling such trenches. Such a polysilicon layer can provide contact to well regions. One set of manufacuturing steps for forming complementary four terminal SOI JFETs will be illustrated with reference to FIGS. 6A to 6K.

Referring now to FIG. 6A, a cross sectional diagram illustrating an implantation step to form an n-well 474 acccording to an embodiment. The cross-sectional diagram of FIG. 6A is taken along the 4B-4B line of FIG. 4A. N-well 474 may provide a back gate for a four terminal p-type JFET 400A. The process step illustrated in FIG. 6A may be performed after the isolation structures (STI) 460 have been formed, for example, after process step like those shown by FIG. 3A. A mask 610 can be patterned and etched to expose only the device layer 406 areas in which four terminal p-type SOI JFETs are to be formed. Phosphorous and/or arsenic may be implanted into the exposed portion of device layer 406 to form a well structure to be used as back gate terminal 474. As but one example, such an implant step can include an implant dose in the range of about 1.0×10¹¹/cm² to 1.0×10¹⁴/cm² and with an implant energy in the range of about 1 to 400 KeV.

Referring now to FIG. 6B, a cross sectional diagram illustrating an implantation step to form a channel region 494 according to an embodiment is set forth. The cross-sectional diagram of FIG. 6B is taken along the 4B-4B line of FIG. 4A. The same mask 610 may used as in the formation of the n-well as illustrated in FIG. 6A. Exposed regions may be subject to an ion implantation step with a p-type dopant such as boron, indium, or thallium to form a p-type region, which can be a channel region 192 of a p-type JFET. In one particular example, an implant dose can be in the range of about 2.0×10¹¹/cm² to 1.0×10¹⁴/cm². An implant energy can be in the range of about 1 to 100 KeV.

Subsequently, mask layer 610 may be removed.

Referring now to FIG. 6C, a cross sectional diagram illustrating an implantation step to form a p-well 414 according to an embodiment is set forth. The cross-sectional diagram of FIG. 6C is taken along the 4B-4B line of FIG. 4A. P-well 414 may provide a back gate for a four terminal n-type JFET 400A The process step illustrated in FIG. 6C may be performed after the isolation structures (STI) 460 have been formed, for example, after process steps like those shown in FIG. 3A. A mask 620 can be patterned and etched to expose only the device layer 406 in which four terminal n-type SOI JFETs are to be formed. Boron may be implanted into the exposed portion of device layer 406 to form a well structure to be used as back gate terminal 414. As but one example, an implant dose can be in the range of about 1.0×10¹¹/cm² to 1.0×10¹⁴/cm² and an implant energy can be in the range of about 1 to 400 KeV.

Referring now to FIG. 6D, a cross sectional diagram illustrating an implantation step to form a channel region 450 according to an embodiment is set forth. The cross-sectional diagram of FIG. 6D is taken along the 4B-4B line of FIG. 4A. The same mask 620 may used as in the formation of the n-well as illustrated in FIG. 6C. Exposed regions may then be subject to an ion implantation step with an n-type dopant such as arsenic, phosphorous, or antimony may be performed to form an n-type region, which can be a channel region 450 of an n-type JFET. In one particular example, an implant dose can be in the range of about 2.0×10¹¹/cm² to 1.0×10¹⁴/cm². An implant energy can be in the range of about 1 to 100 KeV may be used.

Subsequently, mask layer 620 may be removed.

Referring now to FIG. 6E, a cross-sectional diagram of the semiconductor device illustrating an etching step to form a contact to a well 414 (i.e. a back gate for a four terminal n-type JFET) according to an embodiment is set forth. The cross-sectional diagram of FIG. 6E is taken along the 4C-4C line of FIG. 4A.

After the channel implant step of FIG. 6D, a mask layer 624 may be patterned and etched to expose only the desired cut region 638. The isolation regions under cut regions 638 may be etched to expose the sidewall of the active area 630 to include channel 450 and back gate 414. It is noted that because JFETs operate using p-n junctions, the alignment of cut regions need not be as critical as a cases in which a gate oxide is formed over an active area, such as in the case of a MOSFET device. For MOSFET structures, care must be taken not to inadvertently etch the gate oxide and thereby shorting out a control gate. A similar cross section for a p-type four terminal JFET may be essentially the same as in FIG. 6E, except conductivity types are reversed.

Subsequently, mask layer 624 may be removed.

Referring now to FIG. 6F, a cross-sectional diagram of a semiconductor device following the formation of a polysilcon layer 602 over device layer 406 according to an embodiment is set forth. The cross-sectional diagram of FIG. 6F is taken along the 4B-4B line of FIG. 4A. A mask layer 626 may be patterned and etched over the semiconductor device to expose only portions (604 and 608) of polysilicon layer 602 which may later be used to provide source and drain contacts of an n-channel JFET. An implant step may then be performed of with n-type impurities such as phosphorous, arsenic, or antimony with a dose in the range of about 1.0×10¹³/cm² to 1.0×10¹⁶/cm². The implant energy may be sufficient to provide n-type impurities into source and drain (432 and 422). It is noted that polysilicon layer 602 may also be formed in cut regions 638.

Subsequently, mask layer 626 may be removed.

Referring now to FIG. 6G, a cross sectional diagram of a semiconductor device following the pattern and etch of a mask layer 628. Mask layer 628 may be patterned and etched over the semiconductor device to expose only portions (640 and 614) of polysilicon layer 602 which may later be used to provide source and drain contacts of a p-channel JFET. An implant step may then be performed of with a p-type impurity, such as boron, with a dose ranging between 1.0×10¹³/cm²to 1.0×10¹⁶/cm². The implant energy may be sufficient to provide n-type impurities into source and drain (482 and 492).

Subsequently, mask layer 628 may be removed.

Referring now to FIG. 6H, a cross sectional diagram of a semiconductor device following the pattern and etch of a mask layer 634 according to an embodiment is set forth. The cross-sectional diagram of FIG. 6H is taken along the 4B-4B line of FIG. 4A. Mask layer 634 may be patterned and etched over the semiconductor device to expose only a portion 612 of polysilicon layer 602 which may later be used to provide a gate contact of a p-channel JFET. An implant step may then be performed of with n-type impurities such as phosphorous, arsenic, or antimony with a dose in the range of about 1.0×10¹³/cm² to 1.0×10¹⁶/cm².

Subsequently, mask layer 634 may be removed.

Referring now to FIG. 6I, a cross sectional diagram of a semiconductor device following the pattern and etch of a mask layer 636. The cross-sectional diagram of FIG. 6D is taken along the 4B-4B line of FIG. 4A. Mask layer 636 may be patterned and etched over the semiconductor device to expose only a portion 606 of polysilicon layer 602 which may later be used to provide a gate contact of a n-channel JFET. An implant step may then be performed of with with a p-type impurity, such as boron, with a dose ranging between 1.0×10¹³/cm² to 1.0×10¹⁶/cm².

Subsequently, mask layer 636 may be removed.

Referring now to FIG. 6J, a cross sectional diagram of a semiconductor device following the formation and selective doping (FIGS. 6F to 6I) of a polysilicon layer according to an embodiment is shown in a cross sectional view. The cross-sectional diagram of FIG. 6J is taken along the 4B-4B line of FIG. 4A. A method can include depositing a polysilicon layer 602 over a device layer 406. In one particular example, a polysilicon layer 602 can have a thickness in the range of about 100 and 10,000 angstroms. Multiple layers consisting of Si—Ge—C (silicon germanium carbon) alloys of varying composition may also be used for layer 602.

Referring still to FIG. 6J, a polysilicon layer 602 can be selectively doped to form differently doped regions. Such differently doped regions can form source, drain, and gate contacts of JFETs. Such differently doped regions can be formed with masking and ion implantation techniques. If a polysilicon layer 602 is initially undoped, separate implant masks can be utilized for n-doped and p-doped regions. Highly doped n+ type poly regions for source/drain contacts for n-type JFETs may share an implant step with n-type poly regions for forming gate contacts for p-type JFETs, or may be separately doped. Similarly, highly doped p+type poly regions for forming source/drain contacts for p-type JFETs may share an implant step with p-type poly regions for forming gate contacts for n-type JFETs, or may be separately doped. If a polysilicon layer 602 is doped in situ to a particular conductivity type, an implantation step can be omitted.

It is understood that regions 604 and 608 can have a different dopant concentration than region 612 and thus these regions can be subject to a seperate implantation step. Regions 640 and 614 can have a different dopant concentration than region 606 and thus can be subject to a seperate implantation step.

A protective layer (not shown) may be formed on polysicon layer 602 during such ion implantation steps.

Referring now to FIG. 3K, a cross sectional diagram of a semiconductor device following the outdiffusion of polysilicon dopants following an anneal step, such as a rapid thermal anneal, is shown in a cross sectional view. The cross-sectional diagram of FIG. 6J is taken along the 4B-4B line of FIG. 4A. A method can include impurities implanted into polysilicon layer 602 out diffusing into various underlying regions of device layer 406, to form all or a portion of source/drains (422, 432, 482, and 492), and gates (412 and 472) in a device layer 406. Generally, the thickness of device layer 406 may be such that the dopant implantation in previous steps may be such as to drive the appropriate dopants into the regions of device layer not covered by the mask layers.

Referring again to FIG. 6K, it is noted that in other embodiments, source/drain regions (422 and 432) for an n-type JFET exposed by an etch mask 642 may be further implanted with n-type impurities to form a link region to provide a low resistance connection between the channel and the source/drain contacts (420 and 430 of FIG. 4B). In the same fashion, exposed source/drain regions (482 and 492) for p-type JFET may be further implanted with p-type impurities to form a link region to provide a low resistance connection between the channel and the source/drain contacts (480 and 490 of FIG. 4B).

Subsequently, mask layer 642 and any other mask layers used for implanting link regions may be removed.

In yet further steps, a metal such as nickel, cobalt, titanium, platinum, palladium, or other refractory metal may be deposited on polysilicon layer 602 to form a suicide to reduce resistance of polysilicon layer 602 and/or provide a low impedance connection thereto.

In this way, a semiconductor device, such as semiconductor device 400 of FIGS. 4A to 4C, having complementary type four terminal SOI JFETs can be formed.

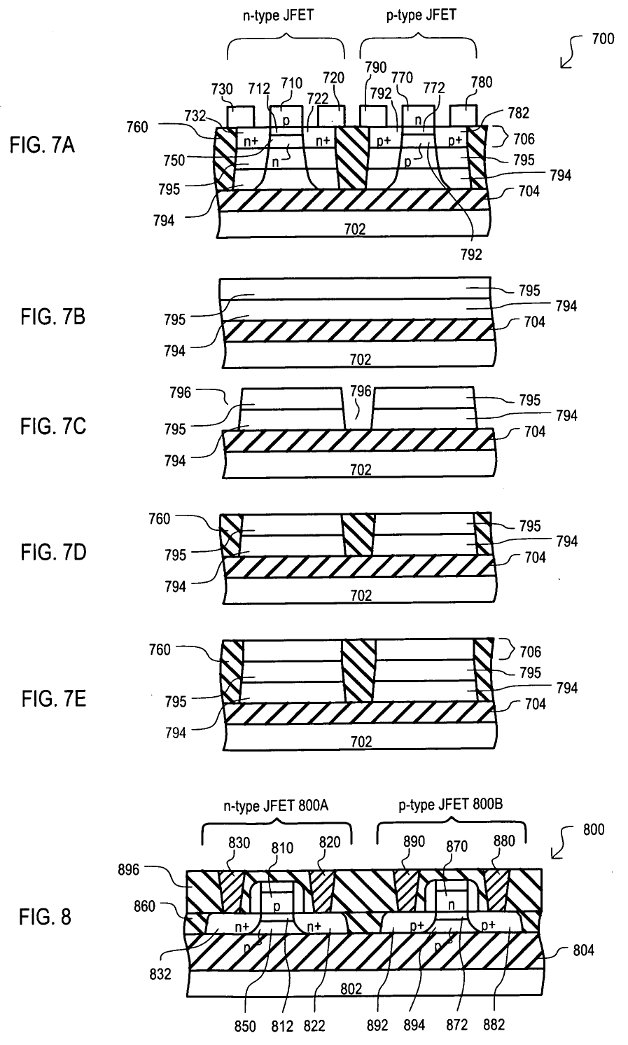

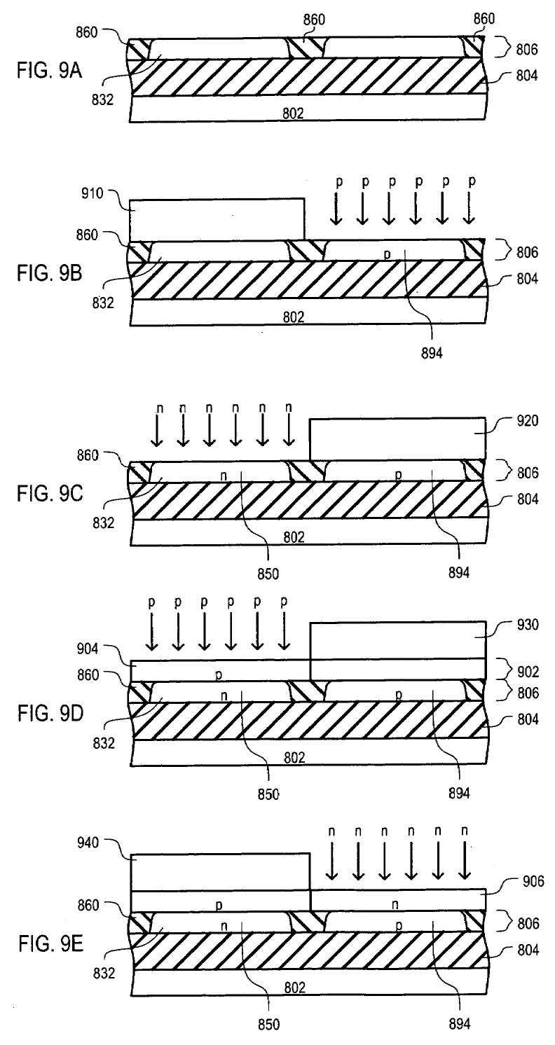

The embodiments set forth above have shown arrangements that include SOI technology. However, other embodiments can include other technology. One such example is shown in FIG. 7A.

Referring now to FIG. 7A, a semiconductor device having complementary JFETs using strained silicon on silicon containing layer on insulator or strained silicon on insulator (SSOI) according to an embodiment is set forth and given the general reference character 700.

Semiconductor device 700 may include similar constituents as semiconductor device 100. Such constituents may have the same reference character except the first digit being a “7” instead of a “1”.

Semiconductor device 700 may differ from semiconductor device 100 in that the base wafer may be a wafer such that insulating layer 704 may be about 30 nm and device layer 706 may be about 5-50 nm. Semiconductor device 700 may include a mono-crystalline silicon layer 794 on top of oxide layer 704. A silicon containing layer 795 of about 100-200 nm can be epitaxially grown on top of mono-crystalline silicon layer 794. Silicon containing layer 795 may be SiGe (silicon germanium), SiGeC (silicon germanium carbon), or the like. If silicon containing layer 795 is SiGe, silicon containing layer 795 may be 10% to 90% germanium and more particularly may be 15% to 35% germanium. The alloy composition of silicon containing layer 795 is varied gradually to prevent silicon containing layer 795 from developing any strain.

Silicon alloy layer 795 may cause epitaxially grown silicon layer 706, which forms the initial device layer, to include a built in strain due to the lattice mismatch between the device layer 706 and silicon alloy layer 795.

A method of manufacturing semiconductor device 700 of FIG. 7A according to an embodiment will now be discussed reference to FIGS. 7B to 7E. FIGS. 7B to 7E are side cross sectional views showing a semiconductor device after various manufacturing steps.

Referring now to FIG. 7B, a cross section diagram of a semiconductor device according to an embodiment after formation of a silicon containing layer is set forth. Initially, a SOI wafer may include a substrate 702 and an insulating layer 704. A mono-crystalline layer 794 and silicon containing layer 795 may be formed on insulating layer 704. Silicon containing layer 795 may be a SiGe alloy or the like. Silicon containing layer 795 may be epitaxially grown on top of mooncrystallinee silicon layer 794. The alloy composition of silicon containing layer 795 may be varied gradually to prevent silicon containing layer 795 from developing any strain.

Referring now to FIG. 7C, a cross section diagram of a semiconductor device according to an embodiment after formation of trenches is set forth. A mask layer (not shown) may be formed, patterned and etched to provide an etching barrier. Silicon containing layer 795 and mono-crystalline silicon layer 794 may then be etched to form trenches 796. The mask layer may then be removed resulting in the semiconductor device of FIG. 7C.

Referring now to FIG. 7D, a cross section diagram of a semiconductor device according to an embodiment after formation of isolation structures is set forth. First, an insulating material may be deposited over the surface and within trenches 796 (from FIG. 7C). A resulting structure can be planarized. For example, a chemical mechanical polishing (CMP) step can remove a deposited insulating material down to silicon containing layer 795. In this way, isolation structure 760 may be at least partially formed.

Referring now to FIG. 7E, a cross section diagram of a semiconductor device according to an embodiment after formation of a device layer and an insulation structure is set forth. Next, a device layer 706 may be grown selectively only on the exposed top surface of silicon containing layer 795. Device layer may be silicon, or strained silicon due to lattice mismatch between Si—Ge layer 795 and the Si layer 706, or the like. In an alternate embodiment, an insulation layer may be deposited over the surface and filling the gaps between silicon containing layer 795. A resulting structure may be planarized. For example, a chemical mechanical polishing (CMP) step can remove a deposited insulating material down to device layer 706. In this way, isolation structure 760 may be formed.

Subsequent process steps may essentially follow the process steps illustrated in FIGS. 3B to 3I, for example. Or in case of a four terminal JFET structure, process steps set forth in FIGS. 6A through 6K may be followed.

In yet another embodiment, a strained silicon on insulator (SSOI) complementary JFET structure may be formed by providing the trench isolation step after the formation of device layer 706. In this case, the trench isolation step may etch through the device layer 706, silicon containing layer 795, and mono-crystalline silicon layer 794 down to the surface of isolation layer 704.

In the embodiments illustrated in FIG. 1 and FIG. 7, a boron implant may be performed under the insulating layer (704 or 104) under regions containing n-channel JFETs and a phosphorous or arsenic implant may be performed under the insulating layer (704 or 104) under regions containing n-channel JFETs. In this way, an inversion layer may be created and capacitance may be reduced.

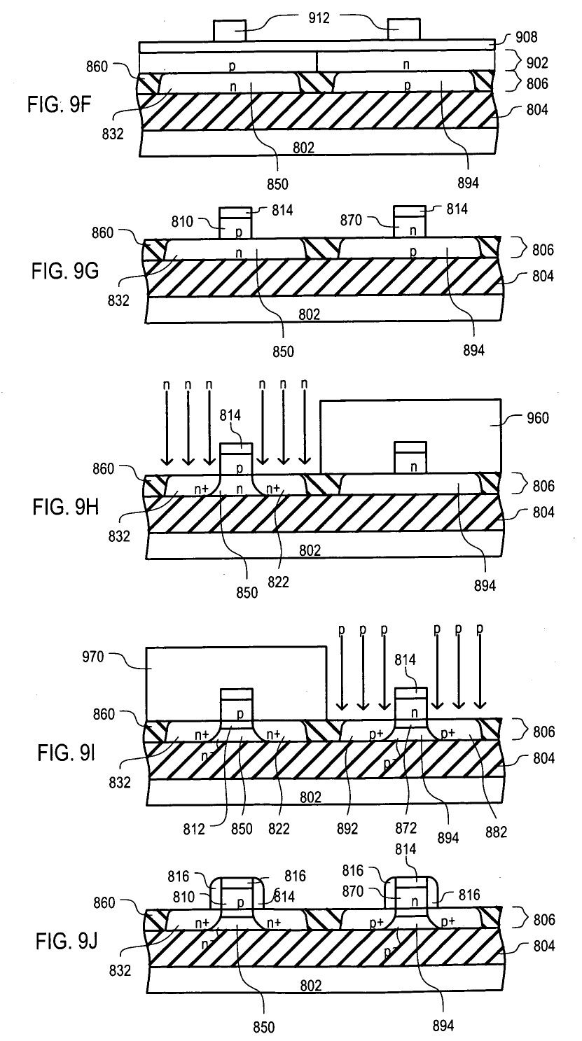

Referring now to FIG. 8, a cross sectional diagram of a complementary SOI JFET according to an embodiment is set forth and given the general reference character 800. Complementary SOI JFET 800 may be compatible with a complementary SOI MOSFET process.

Complementary SOI JFET 800 may include a n-type SOI JFET 800A and a p-type SOI JFET 800B formed in a device layer 860 formed on an insulator 804 formed on a substrate 802. N-type SOI JFET 800A may include a control gate terminal 810 providing a connection to a control gate 812, a source/drain contact 820 providing a connection to a first source/drain 822, and a second source drain contact 830 providing an electrical connection to a second source/drain 832. N-type SOI JFET 800A may include a channel region 850 formed between source/drain regions (822 and 832). P-type SOI JFET 800B may include a control gate terminal 870 providing a connection to a control gate 872, a source/drain contact 880 providing a connection to a first source/drain 882, and a second source drain contact 890 providing an electrical connection to a second source/drain 892. P-type SOI JFET 800B may include a channel region 894 formed between source/drain regions (882 and 892).

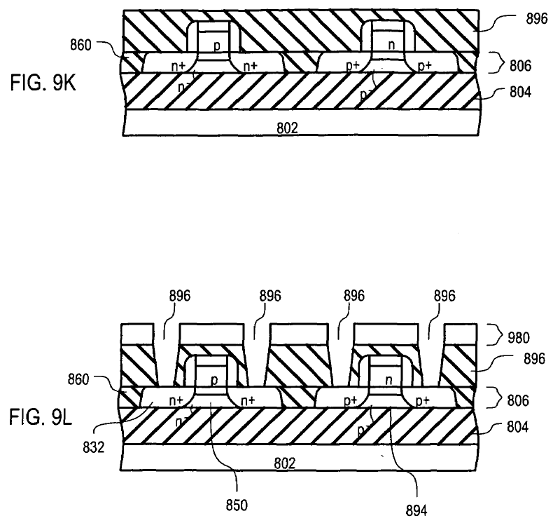

A method of manufacturing semiconductor device 800 including complementary SOI JFETs will now be discussed with reference to FIGS. 9A to 9L.

Referring now to FIG. 9A, a cross sectional diagram of a semiconductor device according to an embodiment after formation of isolation regions is set forth. Initially, a SOI wafer may include a substrate 802, an insulating layer 804, and a device layer 806. Device layer 806 can initially be a layer comprising silicon.

Trenches may be formed through device layer 806 to insulating layer 804 with an etching step. A thermal oxidation step may then be performed to round edges of such trenches. An insulating material may then be deposited over a resulting surface and within the trenches. Preferably such an insulating material can be a silicon oxide layer. A resulting structure can be planarized. For example, a chemical mechanical polishing (CMP) step can remove a deposited insulating material down to a device layer 806 resulting in isolation structures 860 that may separate active regions. Various passive or active devices can be formed in such active regions, including JFETS, such as a p-type JFET or n-type JFET as described above.

A semiconductor device following such steps is shown by FIG. 9A.

Referring now to FIG. 9B, formation of p-type regions are shown in a side cross sectional view. A method can thus include forming a mask layer 910 over regions not subject to a p-type implantation step. Exposed regions may then be subject to an ion implantation step with a p-type dopant such as boron, indium, or thallium to form a p-type region, which can be a channel region 894 of a p-type JFET. In one particular example, an implant dose can be in the range of about 2.0×10¹¹/cm² to 1.0×10¹⁴/cm². An implant energy can be in the range of about 1 to 100 KeV.

Subsequently, a mask layer 910 can be removed.

Referring now to FIG. 9C, formation of n-type regions are shown in a side cross sectional view. A method can thus include forming a mask layer 920 over regions not subject to an n-type implantation. Exposed regions may then be subject to an ion implantation step with an n-type dopant such as arsenic, phosphorous, or antimony may be performed to form an n-type region, which can be a channel region 850 of an n-type JFET. In one particular example, an implant dose can be in the range of about 2.0×10¹¹/cm² to 1.0×10¹⁴/cm². An implant energy can be in the range of about 1 to 100 KeV may be used.

An anneal step such as a rapid thermal anneal may then be performed.

Subsequently, a mask layer 920 can be removed.

Referring now to FIG. 9D, a cross section diagram of a semiconductor device illustrating an implant of a polysilicon layer according to an embodiment is set forth. After mask layer 920 is removed, a polysilicon layer 902 may be deposited. A hard mask layer 930 may be patterned and etched to expose a region 904 of polysilicon layer 902. An implant step may then be performed of with with a p-type impurity, such as boron, with a dose ranging between 1.0×10¹³/cm² to 1.0×10¹⁶/cm².

Subsequently, a mask layer 930 can be removed.

Referring now to FIG. 9E, a cross section diagram of a semiconductor device illustrating an implant of a polysilicon layer according to an embodiment is set forth. After mask layer 930 is removed, a hard mask layer 940 may be patterned and etched to expose a region 906 of polysilicon layer 902. An implant step may then be performed of with with n-type impurities such as phosphorous, arsenic, or antimony with a dose in the range of about 1.0×10¹³/cm² to 1.0×10¹⁶/cm².

Subsequently, a mask layer 940 can be removed.

Referring now to FIG. 9F, a cross sectional diagram or a semiconductor device illustrating a cap layer and gate etch mask according to an embodiment is set forth. A cap layer 908 may be formed over polysilicon layer 902. Cap layer 908 may be an oxide, nitride or the like, as just two particular examples. A hard mask layer 912 may be patterned and etched to provide a mask for a gate etching step.

Referring now to FIG. 9G, a cross sectional diagram of a semiconductor device after a gate etch step according to an embodiment is set forth. An etch step on cap layer 908 and polysilicon layer 902 may be performed using mask layer 912 as a mask. Mask layer 912 may be removed and control gate electrodes 810 and 870 may be formed having respective cap layers 814 thereon.

Referring now to FIG. 9H, a cross sectional diagram of a semiconductor device illustrating a source/drain implant according to an embodiment is set forth. A hard mask layer 960 may be patterned and etched to expose the active region of the n-type SOI JFET. An implant step may then be performed of with n-type impurities such as phosphorous, arsenic, or antimony with a dose in the range of about 1.0×10¹³/cm² to 1.0×10¹⁶/cm². The implant energy may be sufficient to provide n-type impurities into source and drain (832 and 822).

Subsequently, mask layer 960 may then be removed.

Referring now to FIG. 91, a cross sectional diagram of a semiconductor device illustrating a source/drain implant according to an embodiment is set forth. A hard mask layer 970 may be patterned and etched to expose the active region of the p-type SOI JFET. An implant step may then be performed of with a p-type impurity, such as boron, with a dose ranging between 1.0×10¹³/cm² to 1.0×10¹⁶/cm². The implant energy may be sufficient to provide n-type impurities into source and drain (882 and 892). An anneal step may then be performed to drive impurities from respective gate terminals (810 and 870) into the device layer 806 to form a control gate 812 for the n-type SOI JFET and a control gate 872 for the p-type SOI JFET.

Subsequently, a mask layer 970 can be removed.

Referring now to FIG. 9J, a cross sectional diagram of a semiconductor device after formation of a gate sidewall layer according to an embodiment is set forth. An insulation layer, such as an oxide layer, nitride layer or the like may be deposited on the surface of the semiconductor device using chemical vapor deposition or the like. An anisotropic etch may then be performed such that sidewall layers 816 may be formed on the side walls of gates (810 and 870) and cap layers 814.

Referring now to FIG. 9K, a cross sectional diagram of a semiconductor device after formation of an interlevel insulation layer according to an embodiment is set forth. An interlevel insulation layer 896, such as an oxide layer or the like may be deposited on the surface of the semiconductor device using chemical vapor deposition or the like. An anisotropic etch may then be performed such that sidewall layers 816 may be formed on the side walls of gates (810 and 870) and cap layers 814.

Referring now to FIG. 9L, a cross sectional diagram of a semiconductor device after formation of contact holes according to an embodiment is set forth. A mask layer 980 may then be patterned and etched to expose portions of interlevel insulating layer 896 in which contact holes are to be formed. An anisotropic etch may then be performed to provide contact holes 982 exposing source/drain regions (822, 832, 882, and 892).

In a next step, a conductor, such as tungsten or the like may be deposited over the surface filling contact holes 982. After a chemical mechanical polish (CMP) step, a semiconductor device as illustrated in FIG. 8 may be formed.

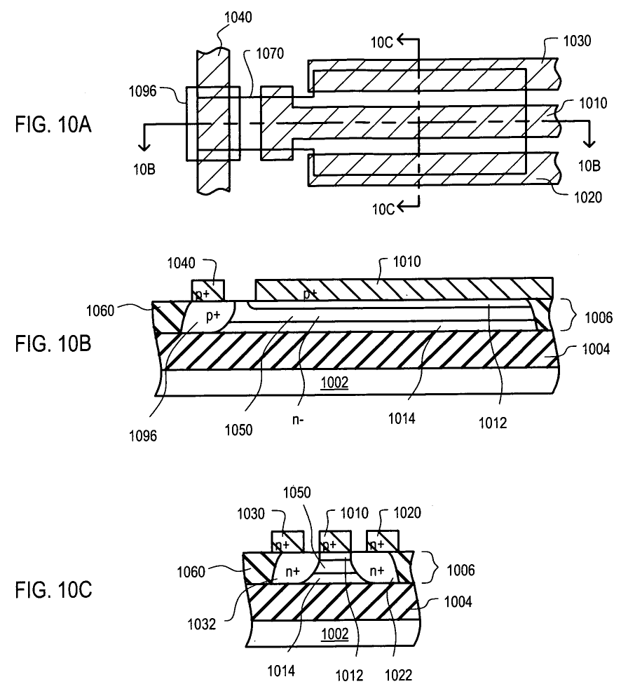

Referring now to FIGS. 10A to 10C, a four terminal SOI JFET having a back gate contact different than the four terminal SOI JFET of FIGS. 4A to 6K is set forth.

FIG. 10A is a plan diagram of a four terminal SOI JFET according to an embodiment. The four terminal SOI JFET of FIG. 10A includes a gate contact 1010, a first source/drain contact 1020, a second source/drain contact 1020, and a back gate contact 1040, each may comprise polysilicon. A well contact implant area 1096 may be provided to form an implant window for the appropriate type impurities in an active region 1070 to provide an electrical connection from the back gate contact 1040 to a back gate formed by a well structure. In the case of an n-type four terminal SOI JFET, the well contact implant area may be implanted with p-type impurities and in the case of a p-type four terminal SOI JFET, the well contact implant area may be implanted with n-type impurities.

Referring now to FIG. 10B, a cross section of a four terminal SOI JFET according to an embodiment is set forth. FIG. 10B is a cross section through line 10B-10B of FIG. 10A. The four terminal SOI JFET of FIG. 10B may include a device layer 1006 formed on an insulating layer 1004 formed on a substrate 1002. The device layer may include a back gate 1014 formed from a well doped with p-type impurities in a similar manner as discussed with respect to FIG. 6C. A well contact region 1096 may be provided to provide an electrical connection from a back gate terminal 1040 to the back gate 1014. The well contact region 1096 may be formed by implanting p-type impurities in a similar manner as illustrated when implanting to form source/drain junctions of FIG. 6G. A channel region 1050 may be formed having n-type impurities in a similar manner as illustrated in FIG. 6D. A control gate 1012 may be formed from out diffused p-type impurities from gate terminal 1010 in a similar manner as discussed with respect to FIG. 6I. Back gate terminal 1040 may be formed from polysilicon doped with p-type impurities in a similar manner as illustrated in FIG. 6G.

Referring now to FIG. 10C, a cross section of a four terminal semiconductor device according to an embodiment is set forth. FIG. 10C is a cross section of the semiconductor device of FIG. 10A along the 10C-10C line. The four terminal semiconductor device of FIG. 1C includes n-doped source/drain terminals (1020 and 1030) and p-doped gate terminal 1010. P-doped gate terminal can provide a contact to p-type control gate 1012. A back gate (control gate) 1014 may formed by implanting a well with p-type impurities. The back gate 1014 may be controlled by a back gate terminal 1040 through a well contact region 1096 (FIG. 10B). In this way, a controllable impedance path may be formed through n-type channel region 1050 between first and second source/drains (1022 and 1032). The impedance path may be controlled by control gate 1012 by way of gate terminal 1010 and back gate 1014 by way of back gate terminal 1040.

Note, the four terminal SOI JFET of FIGS. 10A to 10C differs from the four terminal SOI JFETs of FIGS. 4A to 6K in that the back control gate 1014 may be independently controlled from the control gate 1012. By doing so, logic functions may be compressed and/or threshold voltages may be varied, as just two advantages. In this way, overall die size may be reduced.

Although the four terminal SOI JFET illustrated in FIGS. 10A to 10C is a n-type four terminal SOI JFET a p-type four terminal SOI JFET may be formed by reversing the doping types. For example p-type dopants are replaced with n-type dopants and n-type dopants are replaced with p-type dopants. In this way, complementary four terminal SOI JFETs may be formed having independently controllable control gates and back control gates. Reference in the description to “one embodiment” or “an embodiment” means that a particular feature, structure, or characteristic described in connection with the embodiment is included in at least one embodiment of the invention. The appearance of the phrase “in one embodiment” in various places in the specification do not necessarily all refer to the same embodiment. The term “to couple” or “electrically connect” as used herein may in connect through one or more intervening components.

Further it is understood that the embodiments of the invention may be practiced in the absence of an element or step not specifically disclosed. That is an inventive feature of the invention may include an elimination of an element.

While various particular embodiments set forth herein have been described in detail, the present invention could be subject to various changes, substitutions, and alterations without departing from the spirit and scope of the invention. Accordingly, the present invention is intended to be limited only as defined by the appended claims.

What is claimed is:

1. A semiconductor device, comprising:
a device layer formed on an insulator formed on a substrate;
a first junction field effect transistor (JFET) having a first conductivity type and formed in the device layer;
a second JFET having a second conductivity type and formed in the device layer.

2. The semiconductor device of claim 1, wherein:
the first and the second conductivity type JFETs are enhancement mode transistors used to for logic gates.

3. The semiconductor device of claim 1, wherein
the first JFET has a control gate comprising a polysilicon layer having the second conductivity type;
the second JFET has a control gate comprising a polysilicon layer having the first conductivity type.

4. The semiconductor device of claim 1, wherein:
the device layer comprises silicon.

5. The semiconductor device of claim 1, wherein:
the first JFET includes a first control gate and a second control gate.

6. The semiconductor device of claim 5, wherein:
the first control gate and the second control gate are electrically connected to one another.

7. The semiconductor device of claim 6, wherein:
the first control gate and the second control gate are electrically connected by a polysilicon layer.

8. The semiconductor device of claim 1, further including:
a silicon containing layer interposed between the insulator and the device layer.

9. The semiconductor device of claim 8, wherein:
the silicon containing layer comprises silicon and germanium.

10. The semiconductor device of claim 8, wherein:
the silicon containing layer comprises silicon, germanium and carbon.

11. The semiconductor device of claim 8, wherein:
the device layer comprises strained silicon.

12. The semiconductor device of claim 1, wherein:
the device layer comprises multiple layers containing varying compositions of Si, Ge, and C.

13. The semiconductor device of claim 1, wherein:
the first JFET includes a first source/drain and a first source/drain contact comprising polysilicon.

14. The semiconductor device of claim 1, wherein:
the first JFET includes a control gate having a gate sidewall thereon.

15. The semiconductor device of claim 14, further including a capping layer on the control gate.

16. A semiconductor device, comprising:
a first JFET of a first conductivity type and a second JFET of a second conductivity type, the first JFET and second JFET formed on a substrate having an insulating layer formed between the first and second JFET and the substrate.

17. The semiconductor device of claim 16, wherein:
the first and second JFETs are separated from one another by at least one isolation layer in a direction parallel to a substrate surface.

18. The semiconductor device of claim 17, further including:
the isolation layer is a shallow trench isolation layer.

19. The semiconductor device of claim 16, wherein:
the first JFET includes a first control gate on a first side of a channel and a second control gate on a second side of the channel.

20. The semiconductor device of claim 19, wherein:
the first control gate and second control gate are electrically connected.

21. The semiconductor device of claim 19, wherein the first control gate and the second control gate are independently controllable.

22. The semiconductor device of claim 16, wherein:
the first JFET includes a first JFET control gate comprising polysilicon doped to the second conductivity type.

23. The semiconductor device of claim 22, further including:
the second JFET includes a second JFET control gate comprising polysilicon doped to the first conductivity type.

24. The semiconductor device of claim 16, wherein:
the first JFET includes a first JFET source/drain terminal comprising polysilicon doped with to the first conductivity type.

25. The semiconductor device of claim 14, further including:
a layer including silicon and germanium disposed between the first JFET and the intervening insulating layer.

26. The semiconductor device of claim 16, further including:
a layer including varying compositions of silicon, germanium, and carbon disposed between the first JFET and the intervening insulating layer.

27. A method of manufacturing a semiconductor device, including the step of:
forming complementary junction field effect transistors (JFETs) on an insulator formed on silicon.

28. The method of manufacturing a semiconductor device of claim 27,
wherein the step of forming complementary JFETs includes the step of:
forming a device layer on the insulator.

29. The method of manufacturing a semiconductor device of claim 28,
wherein the step of forming complementary JFETs includes the step of:
forming a first control gate for a first conductivity type JFET by out diffusion of impurities of a second conductivity type into the device layer; and
forming a first control gate for a second conductivity type JFET by out diffusion of impurities of the first conductivity type into the device layer;.

30. The method of manufacturing a semiconductor device of claim 29, wherein the step of forming complementary JFETs includes the step of:
forming a second control gate for the first conductivity type JFET by implanting impurities of the second conductivity type into the device layer; and
forming a second control gate for the second conductivity type JFET by implanting impurities of the first conductivity type into the device layer.

31. The method of manufacturing a semiconductor device of claim 30, wherein the step of forming complementary JFETs includes the step of:
forming an electrical connection between the second control gate for the first conductivity type JFET and a gate contact by implanting impurities of the second conductivity type into a first contact region of the device layer; and
forming an electrical connection between the second control gate for the second conductivity type JFET and a gate contact by implanting impurities of the first conductivity type into a second contact region of the device layer.

32. The method of manufacturing a semiconductor device of claim 28, wherein the step of forming complementary JFETs includes the step of:
forming first and second source/drain junctions for a first conductivity type JFET by doping impurities of the first conductivity type into the device layer; and
forming and second source/drain junctions for a second conductivity type JFET by doping impurities of the second conductivity type into the device layer.

33. The method of manufacturing a semiconductor device of claim 32, wherein the step of forming complementary JFETs includes the step of:
forming a source/drain contact to the first source/drain junction for the first conductivity type JFET from polysilicon; and
forming a source/drain contact to the first source/drain junction for the second conductivity type JFET from polysilicon.

34. The method of manufacturing a semiconductor device of claim 32, wherein the step of forming complementary JFETs includes the step of:
forming a source/drain contact to the first source/drain junction for the first conductivity type JFET from a metal; and
forming a source/drain contact to the first source/drain junction for the second conductivity type JFET from a metal.

35. The method of manufacturing a semiconductor device of claim 28, wherein the step of forming complementary JFETs includes the step of:
forming a silicon containing layer between the device layer and the insulator and the device layer includes strained silicon.

36. The method of manufacturing a semiconductor device of claim 35, wherein the silicon containing layer includes SiGe.

37. The method of manufacturing a semiconductor device of claim 28, wherein the step of forming complementary JFETs includes the step of:
forming multiple layers of Si, Ge, and C alloys of varying composition between the device layer and the insulator and the device layer includes strained silicon.

38. The method of manufacturing a semiconductor device of claim 27, wherein the step of forming complementary JFETs includes the step of:
forming a control gate for a first conductivity type JFET including a first conductive layer having a sidewall insulating layer separating the gate of the second conductivity type from the source and drain regions of the first conductivity type.

39. The method of manufacturing a semiconductor device of claim 38, further including the step of:
forming a contact to a first source/drain junction of the first conductivity type JFET, the contact formed by providing a conductive layer in a contact hole.
